(19) United States
(12) Patent Application Publication
(10) Pub. No.: US 2020/0403134 A1
(43) Pub. Date: Dec. 24, 2020

(54) THERMOELEMENT (VARIANTS)

(71) Applicant: OBSCHESTVO S OGRANICHENNOI OTVETSTVENNOSTYU "RUSTEK", Moscow (RU)

(72) Inventors: Zinovy Moiseevich DASHEVSKY, Moscow (RU); Lev Dmitrievich DUDKIN, Moscow (RU); Sergey Yakovlevich SKIPIDAROV, Moscow (RU)

(73) Assignee: OBSCHESTVO S OGRANICHENNOI OTVETSTVENNOSTYU "RUSTEK", Moscow (RU)

(21) Appl. No.: 16/978,726

(22) PCT Filed: Mar. 21, 2018
(86) PCT No.: PCT/RU2018/000176

§ 371 Date: Sep. 7, 2020

(30) Foreign Application Priority Data
Mar. 13, 2018 (RU) 2018108868

(51) Int. Cl. H01L 35/18; H01L 35/16

(52) U.S. Cl. CPC H01L 35/18; H01L 35/16

(57) ABSTRACT

The present invention relates to thermoelectric power generating devices using thermoelectric elements and thereby generating electricity realizing direct conversion of heat to electric power due to difference in temperature. The present invention is targeted on improving thermoelectric efficiency of a thermoelectric device. According to the first variant of the present invention, technical result is achieved by that a) in thermoelectric element consisting of p-type leg and n-type leg jointed in serial electrical circuit, p-type leg is made of polycrystalline textured semiconductor Bi₂Te₃—Sb₂Te₃ alloy with high thermoelectric efficiency in the operating temperature range T>100° C. and b) in p-type leg, heat flux is directed from the hot end to the cold end parallel the crystallographic axis C. According to the second variant of the present invention, technical result is achieved by that a) in thermoelectric element consisting of p-type leg and n-type leg jointed in serial electrical circuit, p-type leg is made of polycrystalline textured semiconductor Bi₂Te₃—Sb₂Te₃ alloy and built up of two parts which are in perfect electrical and thermal contact and b) in part of p-type leg at low-temperature end of thermoelectric element, heat flux is directed from the hot end to the cold end transverse the crystallographic axis C, while in part of p-type leg at high-temperature end of thermocouple, heat flux is directed from the hot end to the cold end parallel the crystallographic axis C.

### FIELD OF THE INVENTION

The present invention relates to thermoelectric power generating devices using thermoelectric elements and thereby generating electricity realizing direct conversion of heat to electric power due to difference in temperature.

### BACKGROUND

High-priority problem in thermoelectric power generation technology is improving thermoelectric efficiency of a thermoelectric device. That achieves by increasing thermoelectric efficiency of thermoelectric materials in a wide range of operating temperatures (from 50° C. to 350° C.) which represents by figure-of-merit of the material, or so-called Z parameter, defined as:

$$Z = \frac{{α}^{2} σ}{κ} , \qquad ( 1 )$$

where α is Seebeck coefficient, σ is electrical conductivity, and κ is thermal conductivity of thermoelectric material.

A thermoelectric element consists of two legs made of p-type and n-type semiconductor materials (p-type and n-type legs, respectively) jointed to form a serial electrical circuit. Currently, ternary solid solutions (alloys) of bismuth and antimony tellurides Bi₂Te₃ and Sb₂Te₃ are considered as the most effective semiconductor materials for p-type legs operating in the temperature range from 50° C. to 350° C. Maximum value of Z parameter at room temperature (300 K) reaches 3×10⁻³ K⁻¹ (where K is absolute temperature in Kelvin). It should be noted that bismuth and antimony tellurides belong to class of semiconductors with anisotropic properties due to features of crystal structure. It induces anisotropy in values of electrical conductivity σ and thermal conductivity κ in direction parallel or transverse the crystallographic axis C (0001). At the same time, Seebeck coefficient α remains isotropic in semiconductor when its electrical conductivity is based on charge carriers of single one type—by electrons in n-type material or holes in p-type material which concentrations are controlled by donors in n-type or by acceptors in p-type, respectively (see B. M. Goltsman, V. A. Kudinov, I. A. Smirnov. Bi₂Te₃ based semiconductor thermoelectric materials. Moscow, Nauka, 1972, pp. 271-275).

However, strong temperature dependence of Z parameter is a limitation of such materials. Drastic fall in Z values with increasing in temperature is caused by thermal generation of minority charge carriers, namely, electrons in p-type material, leading to occurring component of Seebeck coefficient of opposite sign to Seebeck coefficient providing by majority charge carriers—holes. In this case, Seebeck coefficient is described by formula:

$$α = \frac{{α}_{n} {σ}_{n} + {α}_{p} {σ}_{p}}{{σ}_{n} + {σ}_{p}} , \qquad ( 2 )$$

where indices “n” and “p” refer to the parameters defined by electrons and holes, respectively.

The closest prior art solution to present invention is disclosed in Japanese patent No. 2326466 (published on Jun. 10, 2008), which describes manufacturing of mixture (Bi—Sb)₂Te₃ with an excess amount of Te, melting of the mixture, and solidification of the melt. Then formed ingot undergoes a plastic deformation. The thermoelectric element is built of two legs made of p-type and n-type materials and jointed by a metal pad. Above mentioned (Bi—Sb)₂Te₃ based material for manufacturing p-type legs crystallizes in hexagonal structure with anisotropy of electrical and thermal properties. The authors of patent state that in the studied temperature range up to 100° C., a significantly higher thermoelectric efficiency is achieved when heat flux direction is transverse C axis as compared to the case when the heat flux direction is parallel C axis.

### SUMMARY OF THE INVENTION

The aim of the first variant of present invention is to increase thermoelectric efficiency of the thermoelectric element at onset of intrinsic conduction, typically, in operating temperature range starting from 100° C. at cold end of the leg.

The aim of the second variant of present invention is to increase thermoelectric efficiency of the thermoelectric element over entire operating temperature range.

The technical result in the first embodiment is achieved by that a) in the thermoelectric element consisting of p-type leg and n-type leg jointed in serial electrical circuit, p-type leg is made of polycrystalline textured semiconductor Bi₂Te₃—Sb₂Te₃ alloy with high thermoelectric efficiency in the operating temperature range T>100° C. and b) in p-type leg, heat flux is directed from the hot end to the cold end parallel the crystallographic axis C.

The technical result in second embodiment is achieved by that a) in the thermoelectric element consisting of p-type leg and n-type leg jointed in serial electrical circuit, p-type leg is made of polycrystalline textured semiconductor Bi₂Te₃—Sb₂Te₃ alloy and built up of two parts which are in perfect electrical and thermal contact and b) in part of p-type leg at low-temperature end of the thermoelectric element, heat flux is directed from the hot end to the cold end transverse the crystallographic axis C, while in part of p-type leg at high-temperature end of the thermoelectric element, heat flux is directed from the hot end to the cold end parallel the crystallographic axis C.

### BRIEF DESCRIPTION OF THE DRAWINGS

Invention concept is illustrated by FIGS. 1-9.

FIGS. 1, 8, and 9 show different designs of the thermoelectric element, and FIGS. 2 to 7 display dependences of its parameters.

### DETAILED DESCRIPTION OF THE INVENTION

Improved thermoelectric efficiency of the thermoelectric element according to the first embodiment is achieved due to decrease in “negative” effect of minority charge carriers on the value of Seebeck coefficient and, accordingly, Z parameter. This is because Seebeck coefficient becomes anisotropic at elevated temperatures due to intensive thermal generation of minority charge carriers. Therefore, Seebeck coefficient value of p-type leg diced out transverse C axis (standard orientation) becomes less than Seebeck coefficient value of p-type leg diced out parallel C axis. As the result, at higher operating temperatures, maximum Z parameter values are observed in p-type leg diced out parallel C axis.

Materials for practical use in thermoelectric generation applications are always of polycrystalline or composite nature.

The main manufacturing technique of serial bulk materials based on Bi₂Te₃ and related alloys is powder compaction by hot pressing combined with Spark Plasma Sintering (SPS) or hot extrusion.

Presence of evident cleavage planes in Bi₂Te₃ and related alloys ensures obtaining of “flakes” during grinding, which, being packed in a mold, enable manufacturing well-textured ingots (rods) during subsequent pressing. This is decisive point to use of pressing and SPS techniques for compacting materials based on Bi₂Te₃ and related alloys, and uniaxial pressing technique provides manufacturing of bulk anisotropic thermoelectric materials with crystallographic texture both for n-type and p-type legs.

Inherent feature of thermoelectric Bi₂Te₃ and related alloys manufactured by pressing is some self-ordering of grains orientation when cleavage planes are laying mainly perpendicular to the direction of pressing. This is because during grinding, the ingot of starting material splits along the cleavage planes, and powder particles take the form of plates (flakes) which plane coincides with the cleavage plane. The preferential orientation of the grains causes anisotropic properties of pressed materials: σ, κ and Z have the greatest values in the direction perpendicular to the direction of pressing.

SPS technique allows of compacting powders made of materials that are difficult to compact by standard pressing due to the need to use forces exceeding the strength of press tools materials. In addition, SPS process provides sintering of grains without significant heating of whole load of powder, which is valuable for compacting not entirely stable systems, e.g., nano structured powders.

Thermoelectric materials with even better texture can be manufactured by hot extrusion technique of powder compaction. In this case, cleavage planes of grains align strictly parallel to the axis of extrusion. In addition, plastic deformation of material under high hydrostatic pressure provides effective repairing of structural defects and obtaining polycrystalline ingots (rods) with grain size about 10 μm and density above 96% of single crystal one.

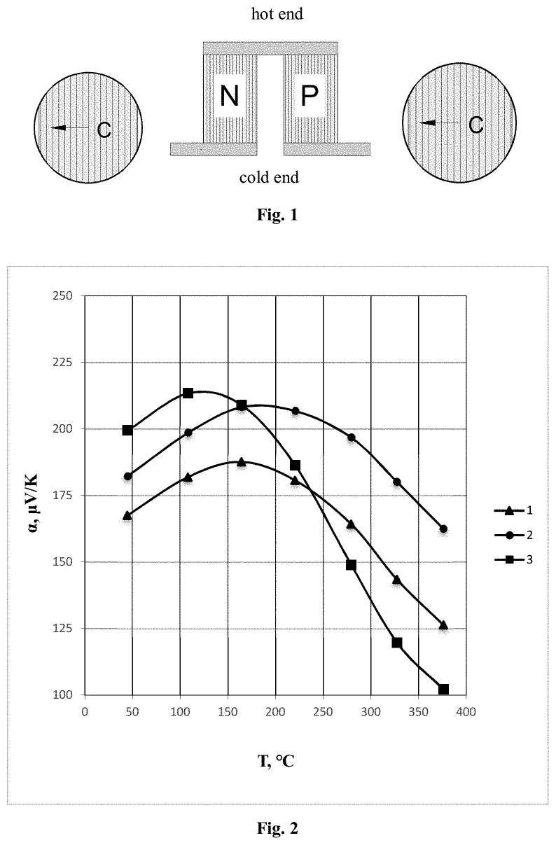

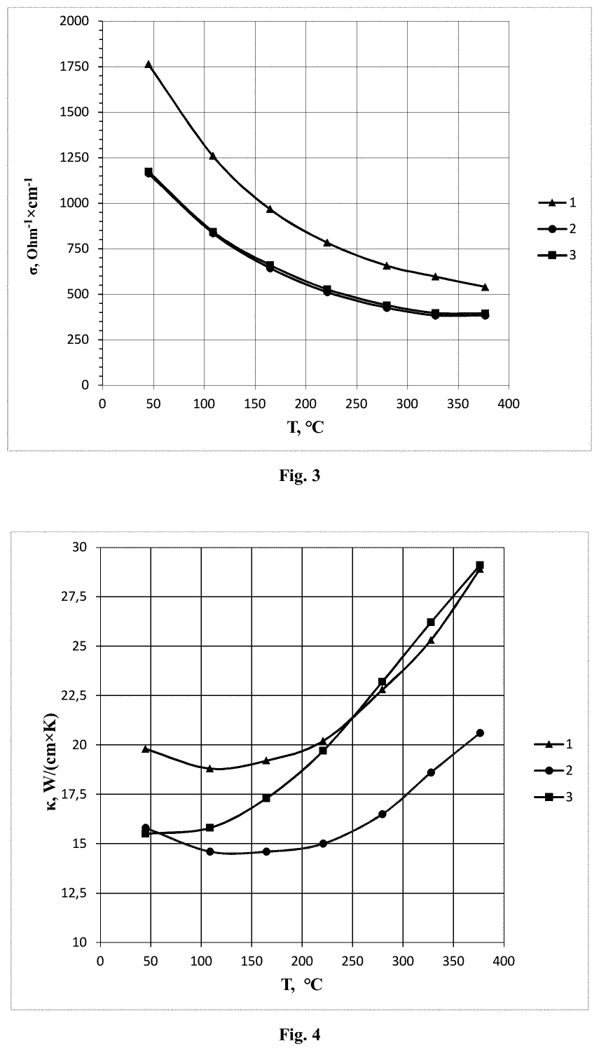

At operating temperatures slightly higher than room temperature when electrical conductivity in n-type and p-type legs is defined by electrons or holes only, direction with maximum Z values is perpendicular to crystallographic axis C. Therefore, legs of the thermoelectric element operating at such temperatures are diced out and positioned so that heat flux is directed from the hot end to the cold end transverse the crystallographic axis C. FIG. 1 shows schematically such configuration, where n-type leg made of Bi₂Te₃ and p-type leg made of Bi₂Te₃—Sb₂Te₃ alloy were diced out and positioned so that heat flux is directed from the hot end to the cold end transverse the crystallographic axis C. This configuration works well for n-type leg in the entire operating temperature range. However, in the case of p-type leg made of Bi₂Te₃—Sb₂Te₃ alloy and operating at temperature higher 100° C. (onset of intrinsic electrical conductivity), Z value of p-type leg diced out parallel C axis is higher than Z value of p-type leg diced out transverse C axis.

FIGS. 2-5 show temperature dependences of α, σ, κ and Z parameters displaying such feature. Curves 1 and 2 in FIGS. 2-5 illustrate dependences of parameters measured on p-type material samples in directions transverse C axis and parallel C axis, respectively.

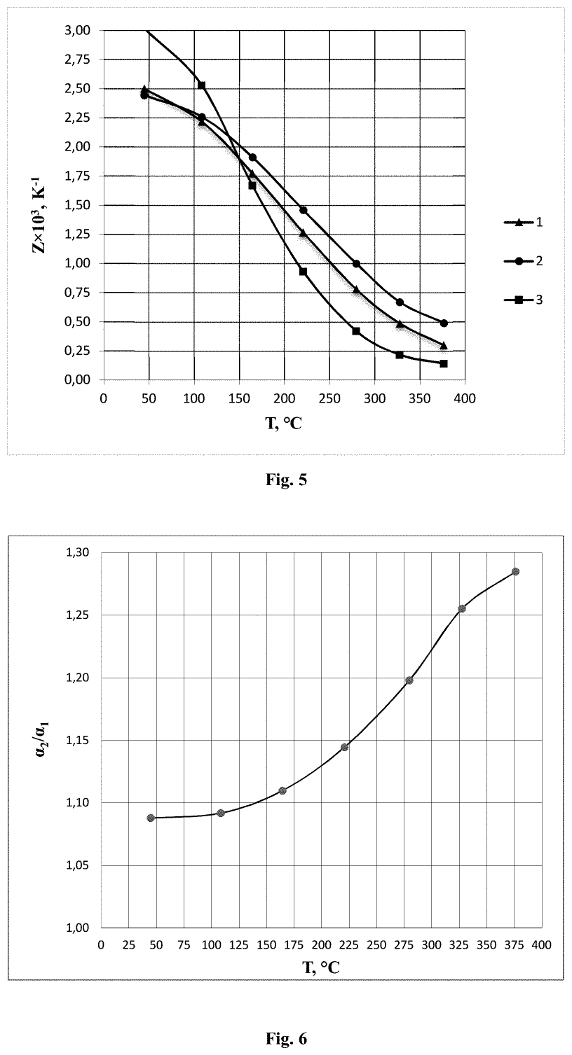

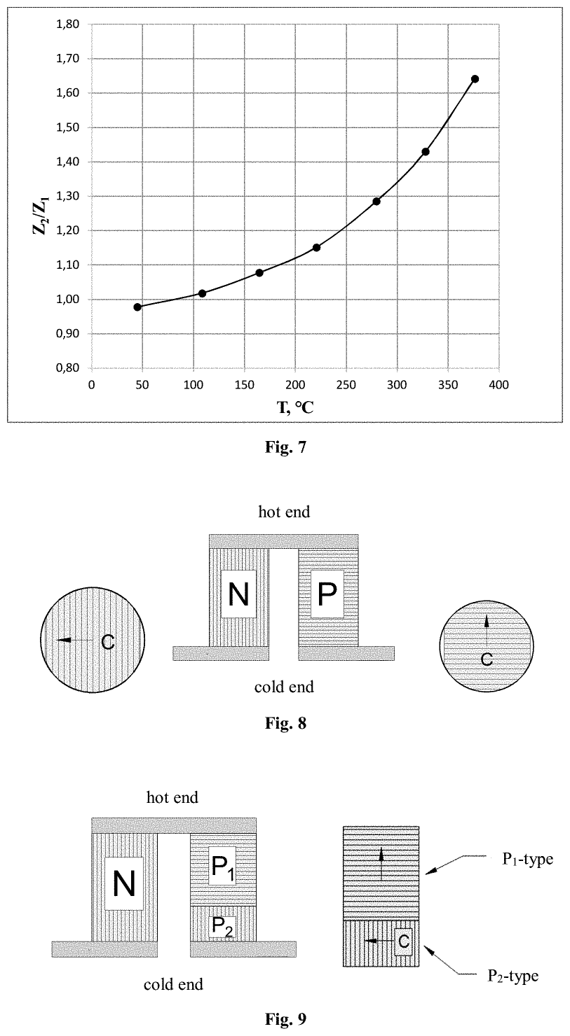

FIG. 6 demonstrate occurrence of strong anisotropy of Seebeck coefficient with increase in temperature. FIG. 7 shows temperature dependence up to 350° C. of ratio between Z value of p-type leg diced out parallel C axis and Z value of p-type leg diced out transverse C axis. This forms the basis to manufacture thermoelectric element in which p-type leg is diced out and positioned in the thermoelectric element so that prevailing orientation of polycrystal coinciding to C axis is directed parallel to heat flux (see FIG. 8). It results in growth on approximately 30% of average Z value of thermoelement in operating temperature interval from 100 to 350° C.

Maximal value of thermoelectric efficiency Z in specific temperature range is reached at some optimal concentration of majority charge carriers in the material (the wider temperature range, the higher concentration of majority charge carriers is required). Therefore, it is difficult to provide high thermoelectric efficiency in wide temperature range from 50 to 350° C. using material with equal doping level.

FIGS. 2-4 display temperature dependences of σ, κ for p-type material with lower concentration of majority charge carriers which is optimal to operation at near room temperatures (curves 3), and as shown in FIG. 5, Z value of such material is higher than of material with concentration of charge carriers optimized for operation at higher temperatures (curves 1 and 2). But, in low temperature range, Z value is higher in direction transverse C axis (see FIG. 7).

Therefore, to enhance significantly thermoelectric efficiency of thermoelectric element, we propose in second embodiment to manufacture thermoelectric element in which p-type leg is built of two parts diced out with different directions of axes in relation to C axis (see FIG. 9). Bottom part of the leg at cold end (low-temperature part) is diced out and positioned in thermoelectric element so that heat flow in it is directed perpendicular to C axis. Top part of the leg at hot end (high-temperature part) is diced out and positioned in thermoelectric element so that heat flow in it is directed parallel to C axis.

1. A thermoelectric element comprising a p-type leg and a n-type leg connected in series in an electrical circuit, the p-type leg being made of a polycrystalline textured semiconductor Bi₂Te₃—Sb₂Te₃ alloy, wherein a heat flux from a hot end to a cold end of the p-type leg is directed parallel to a crystallographic axis C, whereby increasing thermoelectric efficiency in operating temperature range T>100° C.

2. A thermoelectric element comprising a p-type leg and a n-type leg connected in series in an electrical circuit, wherein the p-type leg is made of a polycrystalline textured semiconductor Bi₂Te₃—Sb₂Te₃ alloy and consists of two parts that are in electrical and thermal contact with each other, and wherein in the part of the p-type leg at a low-temperature end of the thermoelectric element, heat flux is directed from a hot end to a cold end perpendicular to a crystallographic axis C, while in the part of the p-type leg at a high-temperature end of the thermoelectric element, heat flux is directed from the hot end to the cold end parallel to the crystallographic axis C.
